(19) United States
(12) Patent Application Publication
(10) Pub. No.: US 2023/0178646 A1
(43) Pub. Date: Jun. 8, 2023

(54) SEMICONDUCTOR DEVICE

(71) Applicant: RENESAS ELECTRONICS CORPORATION, Tokyo (JP)

(72) Inventor: Yu NAGAHAMA, Tokyo (JP)

(21) Appl. No.: 17/954,859

(22) Filed: Sep. 28, 2022

(30) Foreign Application Priority Data
Dec. 3, 2021 (JP) 2021-197291

(51) Int. Cl. H01L 29/78; H01L 29/06; H01L 29/10; H01L 29/40; H01L 29/417; H01L 29/66

(52) U.S. Cl. CPC H01L 29/7811; H01L 29/0623; H01L 29/1095; H01L 29/404; H01L 29/407; H01L 29/41741; H01L 29/7813; H01L 29/401; H01L 29/66727; H01L 29/66734

(57) ABSTRACT

A plurality of first trenches is formed in a cell region and a second trench is formed in an outer peripheral region. A gate electrode and a first field plate electrode are formed in each of the plurality of first trenches, and a second field plate electrode is formed in the second trench. For example, in a drift region formed in the outer peripheral region, a p-type column region is formed in a portion sandwiched, in a Y direction, by a portion, which is located between two of the plurality of first trenches arranged next to each other, and the second trench.

### CROSS-REFERENCE TO RELATED APPLICATIONS

The disclosure of Japanese Patent Application No. 2021-197291 filed on Dec. 3, 2021 including the specification, drawings and abstract is incorporated herein by reference in its entirety.

### BACKGROUND

The present invention relates to a semiconductor device and a method of manufacturing the same, and particularly relates to a semiconductor device having a gate electrode provided inside a trench and a method of manufacturing the same.

In a semiconductor device including a semiconductor element such as a power MOSFET (Metal Oxide Semiconductor Field Effect Transistor), various structures are adopted in order to improve withstand voltage of an outer peripheral region. As such structures, for example, a structure n which a trench gate electrically connected to a source wiring is arranged in an outer peripheral region or a structure in which a p-type impurity region is arranged in an outer peripheral region has been applied.

There are disclosed techniques listed below.

### [Patent Document 1] Japanese Unexamined Patent Application Publication No. 2021-82770

### [Patent Document 2] Japanese Unexamined Patent Application Publication No. 2006-324570

For example Patent Document 1 discloses a multi-trench super junction structure in which a pair of trench gates are provided in one unit cell. In an outer peripheral region surrounding each unit cell, a plurality of p-type impurity regions is arranged in a dot pattern so as not to generate a region where the depletion layer extends incompletely.

Patent Document 2 discloses a power MOSFET in which two electrodes are formed inside a trench. A dummy gate electrode electrically connected to a source wiring is provided in a lower portion of the trench, and a gate electrode electrically connected to a gate wiring is provided in an upper portion of the trench. In an outer peripheral region surrounding each power MOSFET, a p-type impurity region is arranged in a ring shape.

### SUMMARY

In a structure in which a trench gate electrically connected to a source wiring is arranged in an outer peripheral region, some consideration needs to be given to a distance between the trench gate in the outer peripheral region and a trench gate in a cell region. The periphery of each trench gate is depleted at the time of turn-off, but if the above-mentioned distance is too wide, there is a risk that regions where depletion is not sufficient are locally generated, making it impossible to maintain the expected withstand voltage. On the other hand, if the above-mentioned distance is set too narrow in order to achieve sufficient depletion, there is a risk that resolution failure is likely to occur in the exposure process and the trench gate in the outer peripheral region and the trench gate in the cell region are connected.

A main object of this application is to improve the reliability of a semiconductor device by providing a technique capable of sufficiently depleting the outer peripheral region without narrowing the distance between the trench gate in the outer peripheral region and the trench gate in the cell region more than necessary.

Other objects and novel features will be apparent from the description of this specification and accompanying drawings.

An outline of a typical embodiment disclosed in this application will be briefly described as follows.

A semiconductor device according to an embodiment has a cell region in which a plurality of MOSFETs is formed and an outer peripheral region surrounding the cell region in plan view. Also, the semiconductor device includes: a semiconductor substrate having a drift region, a conductivity type of the drift region being a first conductivity type; a body region formed in the drift region of each of the cell region and the out peripheral region, a conductivity type of the body region being a second conductivity type opposite the first conductivity type; a source region formed in the body region of the cell region, a conductivity type of the source region being the first conductivity type; a plurality of first trenches formed in the drift region of the cell region such that a bottom portion of each of the plurality of first trenches reaches a position deeper than the body region; a second trench formed in the drift region of the outer peripheral region such that a bottom portion of the second trench reaches a position deeper than the body region; a plurality of gate electrodes formed in the plurality of first trenches, respectively, via a gate insulating film; and a second electrode formed in the second trench via a second insulating film. Here, each of the plurality of first trenches extends in a first direction in plan view, the second trench extends at least in a second direction crossing the first direction in plan view, in the drift region of the outer peripheral region, a column region is formed in a portion sandwiched, in the first direction, by a portion, which is located between two of the plurality of first trenches arranged next to each other, and the second trench, a conductivity type of the column region being the second conductivity type, and the column region is formed so as to reach a position deeper than the body region.

A semiconductor device according to an embodiment has a cell region in which a plurality of MOSFETs is formed and an outer peripheral region surrounding the cell region in plan view. Also, the semiconductor device includes: a semiconductor substrate having a drift region, a conductivity type of the drift region being a first conductivity type; a body region formed in the drift region of each of the cell region and the outer peripheral region, a conductivity type of the body region being a second conductivity type opposite the first conductivity type; a source region formed in the body region of the cell region, a conductivity type of the source region being the first conductivity type; a plurality of first trenches formed in the drift region of the cell region such that a bottom portion of each of the plurality of first trenches reaches a position deeper than the body region; a second trench formed in the drift region of the outer peripheral region such that a bottom portion of the second trench reaches a position deeper than the body region; a plurality of gate electrodes formed in the plurality of first trenches, respectively, via a gate insulating film; and a second electrode formed in the second trench via a second insulating film. Here, each of the plurality of first trenches extends in a first direction in plan view, the second trench extends at least in a second direction crossing the first direction in plan view, and the second trench has a plurality of projecting portions, each of the plurality of projecting portions protruding in the first direction and protruding toward a portion located between the plurality of first trenches arranged next to each other.

According to the embodiment, it is possible to ensure the reliability of a semiconductor device.

### BRIEF DESCRIPTION OF THE DRAWINGS

FIG. 1 is a plan view showing a semiconductor device according to the first embodiment.

FIG. 2 is a plan view showing the semiconductor device according to the first embodiment.

FIG. 3 is an enlarged plan view showing the principal part of the semiconductor device according to the first embodiment.

FIG. 4 is a cross-sectional view taken along the line A-A in FIG. 3.

FIG. 5 is a cross-sectional view taken along the line B-B in FIG. 3.

FIG. 6 is a cross-sectional view taken along the line C-C in FIG. 3.

FIG. 7 is an enlarged plan view showing the part a semiconductor device according to a studied example.

FIG. 8 is a cross-sectional view showing the semiconductor device according to the first embodiment and the studied example.

FIG. 9 is a cross-sectional view showing the semiconductor device according to the studied example.

FIG. 10 is a cross-sectional view showing the semiconductor device according to the first embodiment.

FIG. 11 is a cross-sectional view showing a manufacturing process of the semiconductor device according to the first embodiment.

FIG. 12 is a cross-sectional view snowing the manufacturing process at the same timing as FIG. 11.

FIG. 13 is a cross-sectional view showing the manufacturing process subsequent to FIG. 12.

FIG. 14 is a cross-sectional view showing the manufacturing process subsequent to FIG. 13.

FIG. 15 is a cross-sectional view showing the manufacturing process at the same timing as FIG. 14.

FIG. 16 a cross-sectional view showing the manufacturing process subsequent to FIG. 15.

FIG. 17 is a cross-sectional view showing the manufacturing process subsequent to FIG. 16.

FIG. 18 is a cross-sectional view showing the manufacturing process at the same timing as FIG. 17.

FIG. 19 is a cross-sectional view showing the manufacturing process subsequent to FIG. 18.

FIG. 20 is a cross-sectional view showing the manufacturing process subsequent to FIG. 19.

FIG. 21 is a cross-sectional view showing the manufacturing process subsequent to FIG. 20.

FIG. 22 is an enlarged plan view showing the principal part of a semiconductor device according to the second embodiment.

FIG. 23 is an enlarged plan view showing the principal part of a semiconductor device according to the first modification of the second embodiment.

FIG. 24 is an enlarged plan view showing a semiconductor device according to the second modification of the first embodiment.

### DETAILED DESCRIPTION

Hereinafter, embodiments will be described in detail with reference to drawings. In all the drawings for describing the embodiments, the members having the same function are denoted by the same reference characters and the repetitive description thereof is omitted. Also, in the following embodiments, the description of the same or similar components is not repeated in principle unless particularly required.

In addition, the X direction, the Y direction, and the Z direction described in this application cross each other and are orthogonal to each other. In the description of this application, the Z direction is defined as a vertical direction, a height direction, or a thickness direction of a certain structure. Further, expressions such as “plan view” or “in plan view” used in this application mean that a plane configured by the X direction and the Y direction is defined as “flat plane” and this “flat plane” is viewed in the direction.

### First Embodiment

### Structure of Semiconductor Device

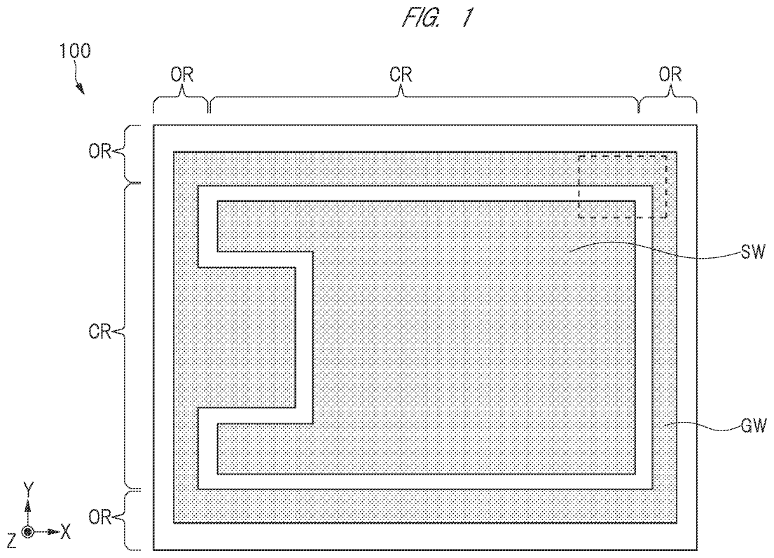

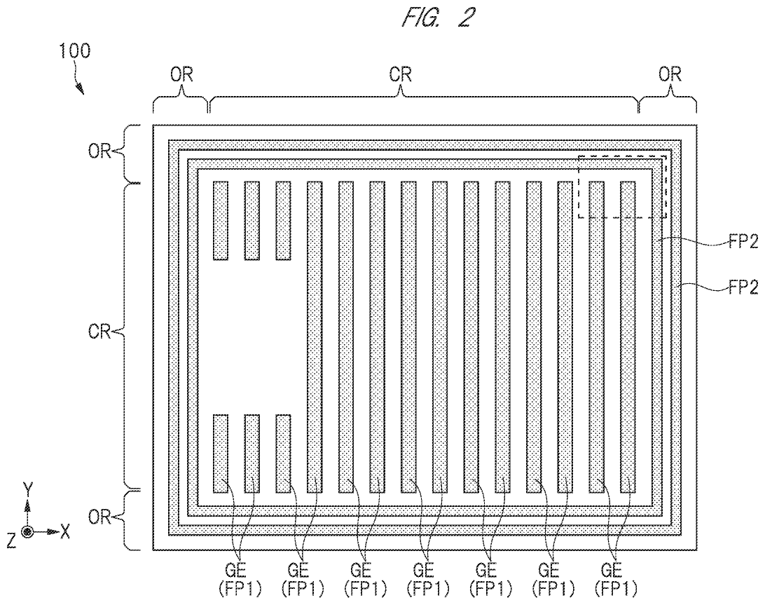

FIG. 1 and FIG. 2 are plan views of a semiconductor chip which is a semiconductor device 100. FIG. 1 mainly shows a wiring formed on a semiconductor substrate SUB, and FIG. 2 shows a structure below the wiring, that is, the structure of a trench gate formed in the semiconductor substrate SUB.

As shown in FIG. 1, most of the semiconductor device 100 is covered with a source wiring SW, and a gate wiring GW is formed around the source wiring SW. Although not shown here, the source wiring SW and the gate wiring GW are covered with a protective film. An opening is provided in a part of the protective film, and the source wiring SW and the gate wiring GW exposed in the opening serve as a source pad and a gate pad. External connection terminals such as wire bonding and a clip (copper plate) are connected to the source pad and the gate pad, so that the semiconductor device 100 is electrically connected to other semiconductor chips or wiring boards.

Also, the semiconductor device 100 includes a cell region CR and an outer peripheral region OR surrounding the cell region CR in plan view. The cell region CR is a region where major semiconductor elements such as a plurality of power MOSFETs are formed.

As shown in FIG. 2, in the cell region CR, a plurality of gate electrodes GE extends in the Y direction. In the outer peripheral region OR, field plate electrodes FP2 extending in the X direction and the Y direction are provided so as to surround the plurality of gate electrodes GE. Although the case where two field plate electrodes FP2 are provided in the outer peripheral region OR is illustrated here, the number of field plate electrodes FP2 may be at least one, and may be three or more.

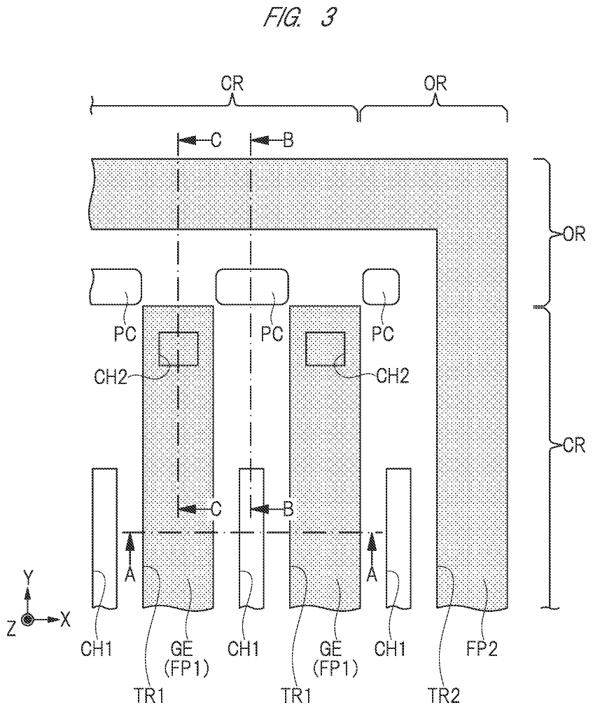

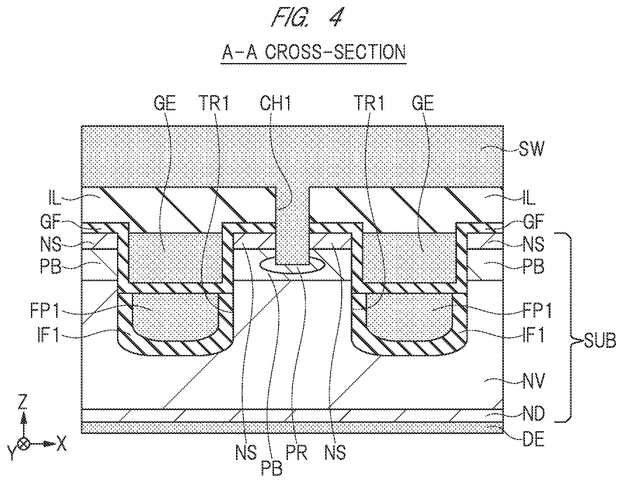

FIG. 3 is a plan view corresponding to the part surrounded by the dashed line shown in FIG. 1 and FIG. 2. FIG. 4 to FIG. 6 are cross-sectional views taken along the line A-A, the line B-B, and the line C-C shown in FIG. 4, respectively.

First, a structure of the power MOSFET formed in the cell region CR will be described with reference to FIG. 3 and FIG. 4.

The semiconductor substrate SUB is made of, for example, n-type silicon and has an n-type drift region NV. A p-type body region PB is formed in the drift region NV. An n-type source region NS is formed in the body region PB. The source region NS has an impurity concentration higher than that of the drift region NV.

A plurality of trenches TR1 is formed in the drift region NV such that their bottom portions reach positions deeper than the body region PB. The plurality of trenches TR extends in the Y direction and is arranged next to each other in the X direction.

A plurality of gate electrodes GE is formed inside the plurality of trenches TR1 via gate insulating films GF, respectively. Further, inside the plurality of trenches TR1 and below the gate insulating films GF and the plurality of gate electrodes GE, a plurality of field plate electrodes FP1 is formed via insulating films IF1, respectively. The gate insulating film GF and the insulating film IF1 are, for example, silicon oxide films. The gate electrode GE and the field plate electrode FP1 are, for example, n-type polycrystalline silicon films. In addition, the thickness of the insulating film IF1 is larger than that of the gate insulating film GF.

Although the gate insulating film GF is formed also on the semiconductor substrate SUB outside the plurality of trenches TR1, this gate insulating film GF may be left as it is or may be removed.

Next, the structure of the outer peripheral region OR will be described with reference to FIG. 3, FIG, 5, and FIG. 6.

The body region PB is formed also in the drift region NV of the outer peripheral region OR. In the drift region NV of the outer peripheral region OR, the trenches TR2 are formed such that their bottom portions reach positions deeper than the body region PB. The trench TR2 extends in the X direction and the Y direction so as to surround the plurality of trenches TR1.

The field plate electrode FP2 is formed inside the trench TR2 via an insulating film IF2. The insulating film IF2 is a film in the same layer as the insulating film IF1, and is, for example, a silicon oxide film. The field plate electrode FP2 is a conductive film in the same layer as the field plate electrode FP1, and is, for example, an n-type polycrystalline silicon film. Also, in the present embodiment, as shown in FIG. 6, the bottom portion of the field plate electrode FP2 reaches the same position as the bottom portion of the field plate electrode FP1. Further, the bottom portion of the insulating film IF2 reaches the same position as the bottom portion of the insulating film IF1. Namely, the thickness of the field plate electrode FP2 is the same as the sum of the thickness of the gate electrode GE, the thickness of the gate insulating film GF, and the thickness of the field plate electrode FP1.

Also, a p-type column region PC is formed in the drift region NV of the outer peripheral region OR. The column region PC is formed to a position deeper than body region PB. The impurity concentration of the column region PC is equal to or higher than that of the body region PB. A main feature of the first embodiment relates to the column region PC, and detailed effects of the column region PC will be described in detail later.

As shown in FIG. 4 to FIG. 6, an n-type drain region ND and a drain electrode DE are formed on the back surface of the semiconductor substrate SUB. The n-type drain region ND has an impurity concentration higher than that of the drift region NV. The drain electrode DE is composed of a single-layer metal film such as an aluminum film, a titanium film, a nickel film, a gold film, or a silver film, or a stacked film in which these metal films are appropriately stacked.

An interlayer insulating film IL is formed on the semiconductor substrate SUB so as to cover the gate electrode GE and the field plate electrode FP2. The interlayer insulating film IL is, for example, a silicon oxide film. A plurality of holes CH1 is formed in the interlayer insulating film IL of the cell region CR. The plurality of holes CH1 penetrates through the interlayer insulating film IL and the source region NS such that their bottom portions are located within the body region PB. A high concentration region PR having an impurity concentration higher than that of the body region PB is formed in the body region PB at the bottom portion of each of the plurality of holes CH1. Also, a plurality of holes CH2 is formed in the interlayer insulating film IL of the outer peripheral region OR. The hole CH2 is formed above the gate electrode GE.

The source wiring SW is formed on the interlayer insulating film IL so as to fill the inside of the hole CH1. The source wiring SW is electrically connected to source region NS, the body region PB, and the high concentration region PR, and supplies source potential thereto. Also, the gate wiring GW is also formed on the interlayer insulating film IL so as to fill the inside of the hole CH2. The gate wiring GW is electrically connected to the gate electrode GE. A gate potential is applied to the gate electrode GE from the gate wiring GW.

Although not shown here, other holes are also formed in the interlayer insulating film IL, and the field plate electrodes FP1 and FP2 are also electrically connected to the source wiring SW via these other holes.

Also, the source wiring SW and the gate wiring GW are composed of, for example, a barrier metal film and a conductive film formed on the barrier metal film. The barrier metal film is, for example, a titanium nitride film, and the conductive film is, for example, an aluminum film.

The source wiring SW and the gate wiring GW may be composed of a plug layer, which fills the inside of the hole CH1 or the inside of the hole CH2, and the barrier metal film and the conductive film formed on the interlayer insulating film IL. In that case, the plug layer is composed of a barrier metal film such as a titanium nitride film and a conductive film such as a tungsten film.

### Matters Studied by Inventors of This Application and Main Features of First Embodiment

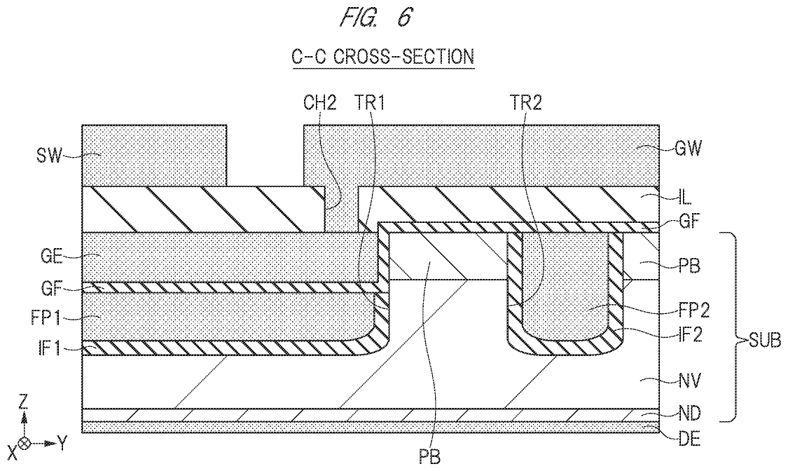

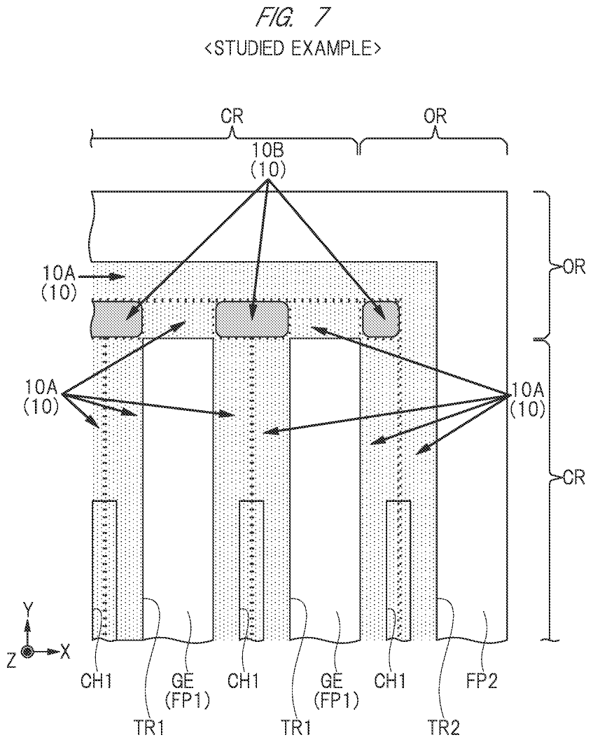

Hereinafter, the semiconductor device according to the studied example studied by the inventors of this application and the problems thereof will be described with reference to FIG. 7 to FIG. 10, and then the main features of the first embodiment will be described. The semiconductor device according to the studied example is similar to the semiconductor device 100 according to the first embodiment except that the column region PC is not provided.

As shown in FIG. 7 to FIG. 9, in the studied example, the depletion layer 10 spreads entirely from the cell region CR to the outer peripheral region OR at the time of turn-off. Therefore, the withstand voltage of the semiconductor device 100 is maintained. However, since the depletion layer 10 spreads around the field plate electrodes FP1 and FP2, a partial depletion occurs in the portion spaced apart from the field plate electrodes FP1 and FP2, while a complete depletion is difficult in the portion spaced apart from the field plate electrodes FP1 and FP2. In FIG. 7 to FIG. 9, a portion where complete depletion occurs is shown as a fully depleted region 10A and a portion where partial depletion occurs is shown as a partially depleted region 10B.

In order to achieve sufficient depletion, it is conceivable to narrow the distance between the trench TR1 and the trench TR2 by, for example, bringing the trench TR2 closer to the end of each trench TR1. However, in that case, if the above-mentioned distance is set to a narrow distance of 0.25 μm or less, there is a risk that resolution failure is likely to occur in the exposure process and the trench TR1 and the trench TR2 are connected.

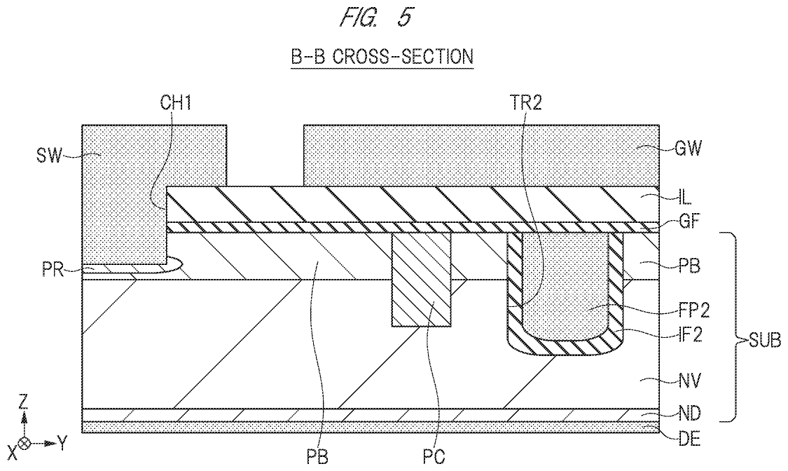

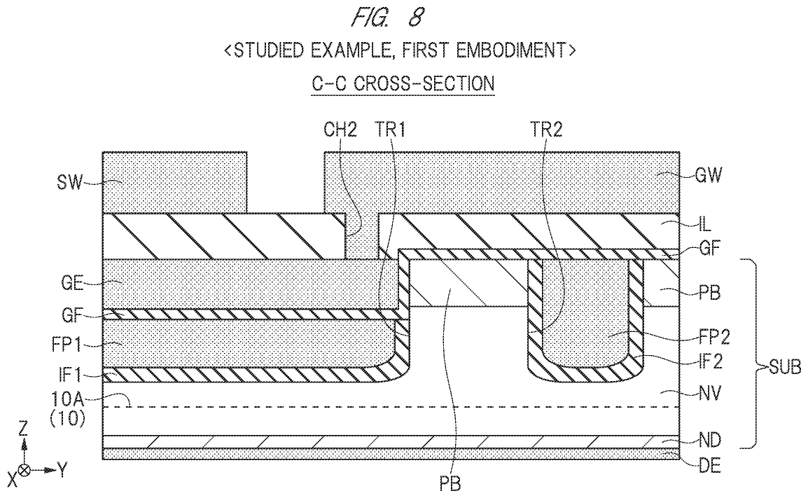

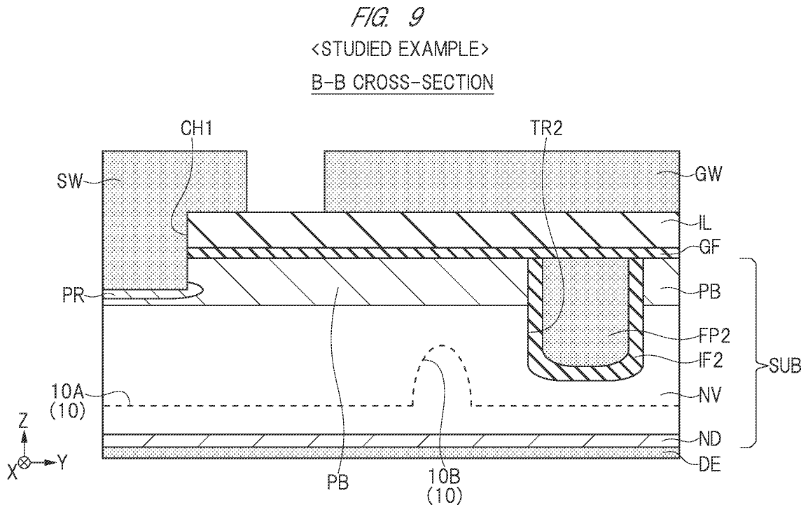

As can be seen by the comparison of FIG. 9 and FIG. 10, in the first embodiment, the p-type column region PC is provided in the portion where the depletion layer 10 does not spread sufficiently (partially depleted region 10B). For example, as shown in FIG. 3 and FIG. 5, a certain column region PC is formed in a portion sandwiched in the Y direction by a portion, which is located between two of the plurality of trenches TR1 arranged next to each other, and the trench TR2, in the drift region NV of the outer peripheral region OR. Also, the column region PC is formed at a position spaced apart from the trench TR2 in the Y direction.

Since the column region PC is electrically connected to the source wiring SW via the body region PB, the source potential is supplied also to the column region PC. Further, the column region PC is formed to a position deeper than the body region PB. This column region PC can completely deplete the partially depleted portion. Therefore, since the withstand voltage in the outer peripheral region OR of the semiconductor device 100 can be improved, the reliability of the semiconductor device 100 can be improved.

Also, the column region PC is formed in the outer peripheral region. OR closer to the trench TR2 than the end of the trench TR1 instead of in the cell region CR where the power MOSFET is formed. Therefore, the increase in on-resistance does not occur due to the column region PC.

In addition, as shown in FIG. 7, a portion where the partial depletion is likely to occur is present also near the corner portion where the trench TR2 extending in the X direction and the trench TR2 extending in the Y direction cross each other. It is preferable to provide the column region PC also in such a portion. Namely, the column region PC is formed also in the drift region NV of the outer peripheral region OR located in a portion sandwiched in the Y direction by a portion, which is between the trench TR1 of the plurality of trenches TR1 closest to the trench TR2 extending in the Y direction and the trench TR2 extending in the Y direction, and the trench TR2 extending in the X direction. Further, this column region PC is formed at a position spaced apart from the trench TR2 in each of the X direction and the Y direction. In this way, the withstand voltage in the outer peripheral region OR of the semiconductor device 100 can be improved.

It is also conceivable to form the column region PC along the trench TR2 in the entire outer peripheral region OR. However, in that case, the column region PC is formed also in a portion where the depletion is originally likely to occur. Then, at that portion, the depletion layer fully spreads at a low voltage, and a breakdown may occur due to electric field concentration if the voltage is further increased. Therefore, it is preferable that the column regions PC separated from each other are locally provided in the outer peripheral region OR as in the first embodiment.

### Method of Manufacturing Semiconductor Device

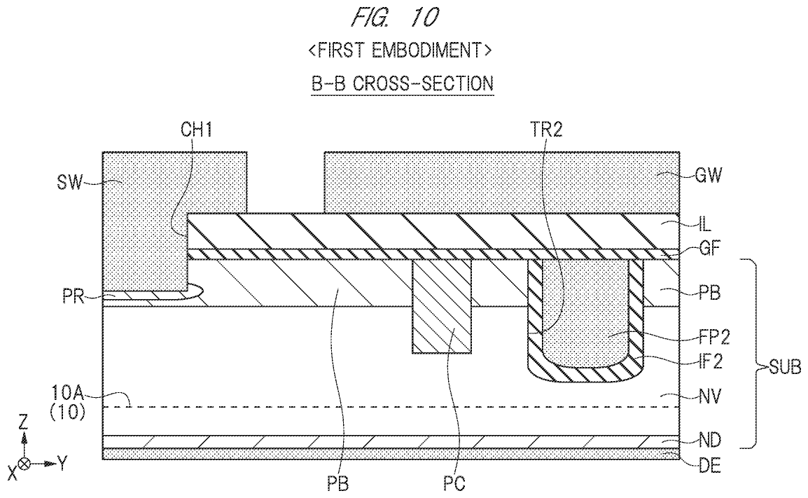

A method of manufacturing the semiconductor device 100 will be described below with reference to FIG. 11 to FIG. 20. In the following description, cross-sectional views taken along the line A-A in FIG. 3 are mainly used, but cross-sectional views taken along the line B-B in FIG. 3 are also used as necessary.

First, as shown in FIG. 11 and FIG. 12, the semiconductor substrate SUB having the n-type drift region NV is prepared. The drift region NV may be the semiconductor substrate SUB itself made of n-type silicon, or may be a semiconductor layer grown on the n-type silicon substrate while introducing phosphorus (P) by the epitaxial growth method.

Next, the plurality of trenches TR1 is formed in the drift region NV of the cell region CR, and the trenches TR2 are formed in the drift region NV of the outer peripheral region OR. In order to form the trenches TR1 and TR2, for example, a silicon oxide film is first formed on the semiconductor substrate SUB by, for example, the CVD method. Next, a resist pattern having openings is formed on the silicon oxide film by the photolithography method. Next, the trenches TR1 and TR2 are formed in the drift region NV by performing the dry etching process using the resist pattern as a mask to the silicon oxide film and the drift region NV exposed from the openings. Thereafter, the resist pattern is removed by the ashing process, and the silicon oxide film is removed by, for example, the wet etching process using hydrofluoric acid.

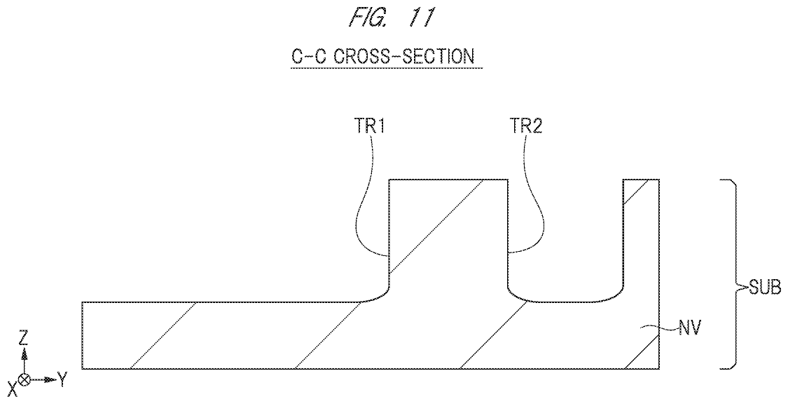

Next, as shown in FIG. 13, the insulating film IF1 made of, for example, a silicon oxide film is formed inside the plurality of trenches TR1 by, for example, the thermal oxidation method. Next, the conductive film CF made of, for example, an n-type polycrystalline silicon film formed on the insulating film IF1 by, for example, the CVD method, so as to fill the inside of the plurality of trenches TR1. Note that the insulating film IF1 and the conductive film CF are formed also inside the trench TR2 in the outer peripheral region OR by the same process.

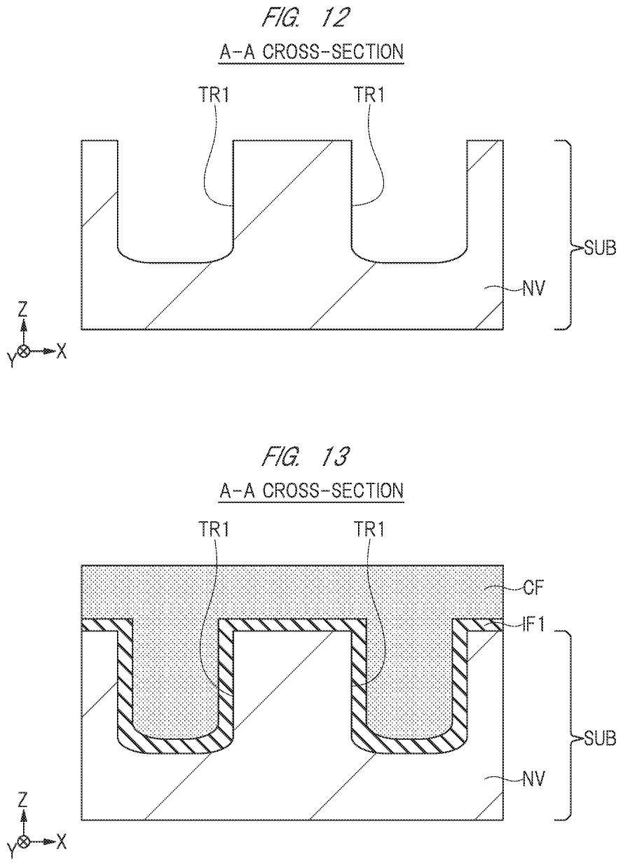

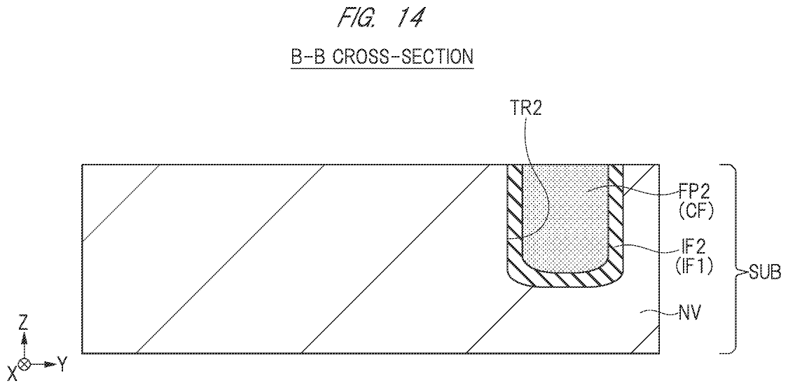

Next, as shown in FIG. 14 and FIG. 15, the conductive film CF and the insulating film IF1 formed outside the plurality of trenches TR1 and TR2 are sequentially removed by, for example, the dry etching process and the wet etching process. In this manner, the field plate electrode FP2 is formed inside the trench TR2 via the insulating film IF2, and the plurality of field plate electrodes FP1 is formed inside the plurality of trenches TR1 via the insulating film IF1, respectively. Here, in order to make the configuration easier to understand, the insulating film IF1 left inside the trench TR2 will be described as the insulating film IF2.

Next, a resist pattern that covers the outer peripheral region OR and opens the cell region CR is formed, and the dry etching process and the wet etching process, for example, are performed using the resist pattern as a mask. In this way, as shown in FIG. 15, the insulating film IF1 and the plurality of field plate electrodes FP1 are selectively recessed inside the plurality of trenches TR1.

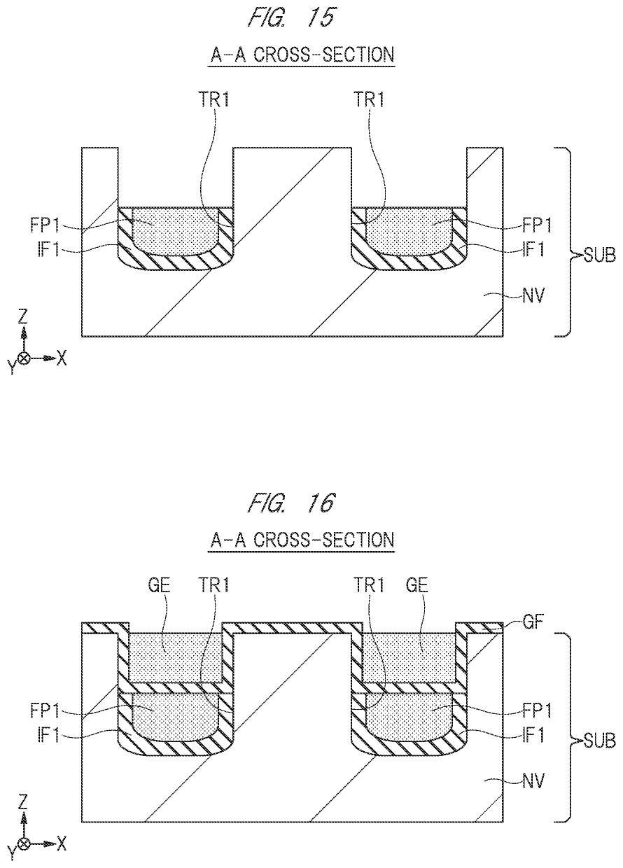

Next, as shown in FIG. 16, the gate insulating film GF made of, for example, a silicon oxide film is formed inside the plurality of trenches TR1 by, for example, the thermal oxidation method. Next, for example, an n-type polycrystalline silicon film is formed by, for example, the CVD method on the gate insulating film GF so as to fill the inside of the plurality of trenches TR1. Next, the polycrystalline silicon film formed outside the plurality of trenches TR1 is removed by, for example, the dry etching process.

In this way, the plurality of gate electrodes GE is formed inside the plurality of trenches TR1 via the gate insulating film GF, respectively. The gate insulating film GF and the gate electrode GE are formed above the insulating film IF1 and the field plate electrode FP1. Thereafter, the gate insulating film GF formed outside the trench TR1 may be removed by the wet etching process or the like.

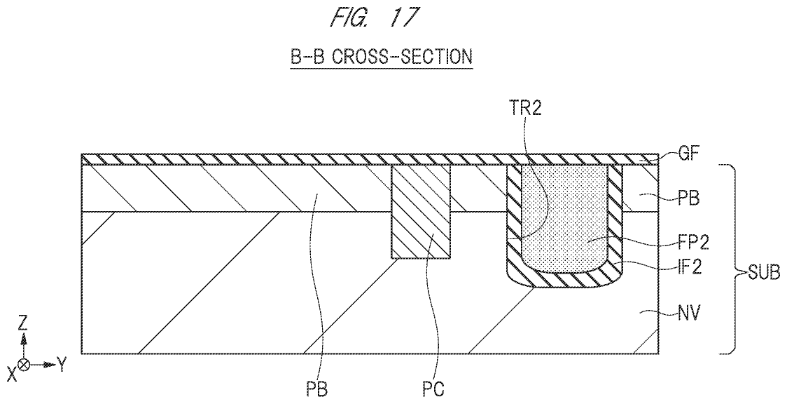

Next, as shown in FIG. 17 and FIG. 18, for example, the p-type body region PB is formed by introducing boron (B) into the drift region NV of the cell region CR and the outer peripheral region OR by the photolithography method and the ion implantation method. Next, for example, the n-type source region NS is formed by introducing arsenic (As) into the body region PB of the cell region CR by the photolithography method and the ion implantation method. Next, for example, the p-type column region PC is formed by introducing arsenic (As) into the drift region NV of the outer peripheral region OR by the photolithography method and the ion implantation method.

Note that, as shown in FIG. 18, the column region PC is formed to a position deeper than the body region PB. Further, the impurity concentration of the column region PC may be the same as that of the body region PB, or may be higher than that of the body region PB. Further, as shown in FIG. 3 and FIG. 5, the column region PC is formed in the drift region NV of the outer peripheral region OR located in the portion sandwiched in the Y direction by the portion between each of the plurality of trenches TR1 and the trench TR2.

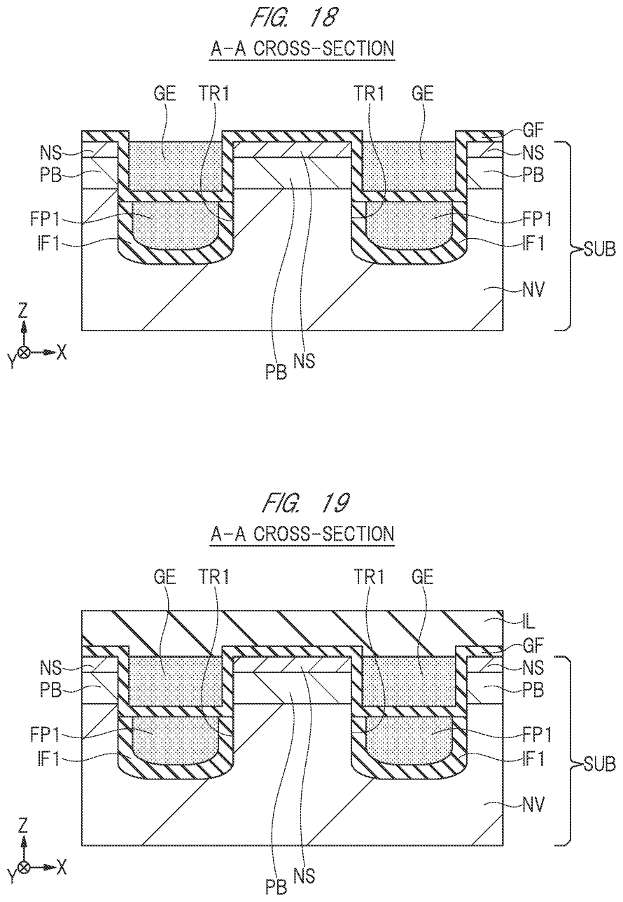

Next, as shown in FIG. 19, the interlayer insulating film IL made of, for example, a silicon oxide film is formed on the semiconductor substrate SUE by, for example, the CVD method, so as to cover the plurality of gate electrodes GE and the field plate electrode FP2.

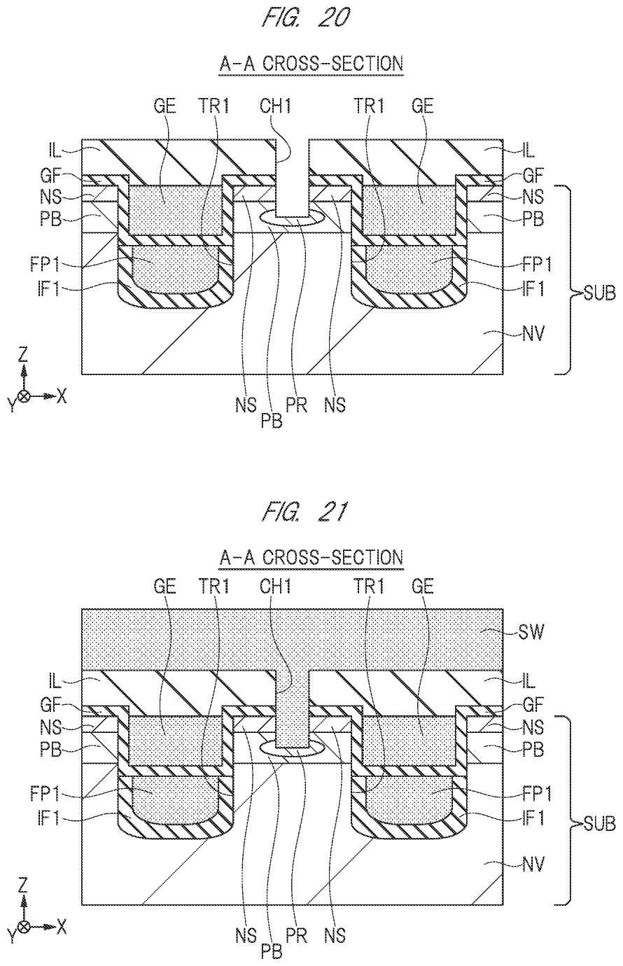

Next, as shown in FIG. 20, the hole CH1 penetrating through the interlayer insulating film IL and the source region NS of the cell region CR is formed by the photolithography method and the dry etching process. In addition, in the step of forming the hole CH1, the hole CH2 is also formed in the interlayer insulating film IL in the outer peripheral region OR. The bottom portion of the hole CH1 is located in the body region PB. Next, the p-type high concentration region PR is formed by introducing, for example, boron (B) into the body region PB at the bottom portion of the hole CH1 by the photolithography method and the ion implantation method.

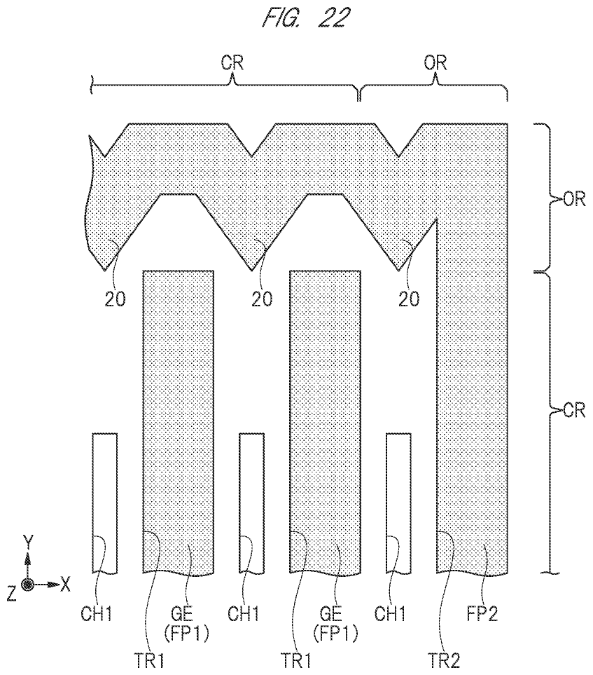

Next, as shown in FIG. 21, the source wiring SW is formed on the interlayer insulating film IL. First, a stacked film of a barrier metal film made of, for example, a titanium nitride film and a conductive film made of, for example, an aluminum film is formed on the interlayer insulating film IL by the sputtering method or the CVD method so as to fill the inside of the hole CH1. Next, the source wiring SW is formed by patterning the stacked film. Although not shown here, the gate wiring GW is also formed on the interlayer insulating film IL so as to fill the hole CH2 by the same step as the step of forming the source wiring SW. Next, a protective film made of, for example, a polyimide film is formed on the source wiring SW and the gate wiring GW by, for example, the coating method. Thereafter, though not shown, a part of the protective film is opened to expose regions to be the source pad and the gate pad on the source wiring SW and the gate wiring GW.

Then, the semiconductor device 100 is manufactured through the following steps. First, the back surface of the semiconductor substrate SUB is polished as required. Next, the n-type drain region ND is formed by introducing, for example, arsenic (As) into the back surface of the semiconductor substrate SUB by the ion implantation method. Next, the drain electrode DE is formed on the drain region ND by the sputtering method. By the process above, the structure shown in FIG. 3 to FIG. 5 is obtained.

### Second Embodiment

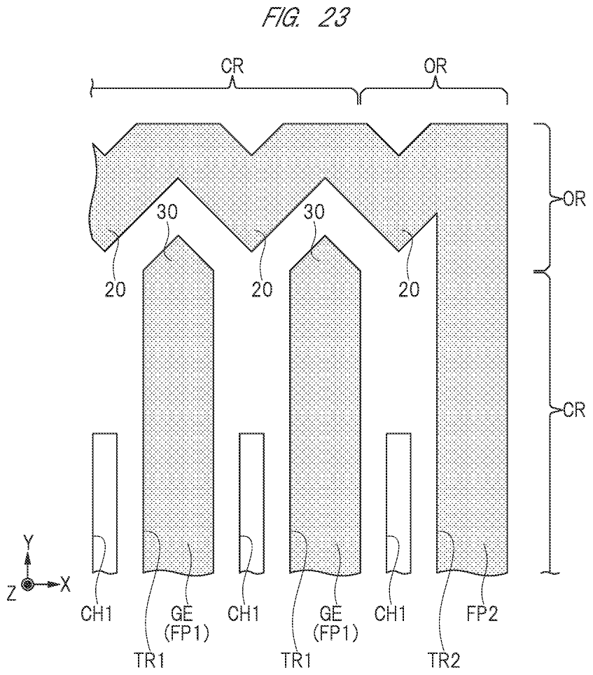

The semiconductor device 100 according to the second embodiment will be described below with reference to FIG. 22. In the following description, differences from the first embodiment will be mainly described, and descriptions of the points that overlap with the first embodiment will be omitted.

In the first embodiment, the p-type column region PC is provided in the portion where the depletion layer 10 does not spread sufficiently. However, in the second embodiment, the column region PC is not provided. Instead, in the second embodiment, as shown in FIG. 22, the trench TR2 extending in the X direction has a plurality of projecting portions 20. Each of the plurality of projecting portions 20 protrudes in the Y direction toward a portion between each of the plurality of trenches TR1.

The field plate electrode FP2 electrically connected to the source wiring SW is formed also inside the projecting portion 20. Therefore, the projecting portion 20 can completely deplete the partially depleted portion. Also in the second embodiment, since the withstand voltage in the outer peripheral region OR of the semiconductor device 100 can be improved, the reliability of the semiconductor device 100 can be improved.

In addition, even in the second embodiment, the portion where the partial depletion is likely to occur is present at the corner portion where the trench TR2 extending in the X direction and the trench TR2 extending in the Y direction cross each other. It is preferable to provide the projecting portion 20 also in such a portion. Namely, one of the plurality of projecting portions 20 protrudes in the Y direction toward the portion between the trench TR1 of the plurality of trenches TR1 closest to the trench TR2 extending in the Y direction and the trench TR2 extending in the Y direction.

Also, the width of each of the plurality of projecting portions 20 in the X direction narrows as it extends toward the portion between each of the plurality of trenches TR1. Processing the projecting portions 20 into such a shape makes it easier to bring the trench TR2 closer to the trench TR1 while suppressing the risk that the trench TR1 and the trench TR2 are connected when forming the trench TR1 and the trench TR2.

The manufacturing method of the second embodiment is substantially the same as the manufacturing method of the first embodiment. The projecting portions 20 can be formed simply by changing the mask for forming the trench TR2 to a mask having a different layout shape. Therefore, since it is not necessary to form the column region PC of the first embodiment, the manufacturing process can be simplified.

### First Modification

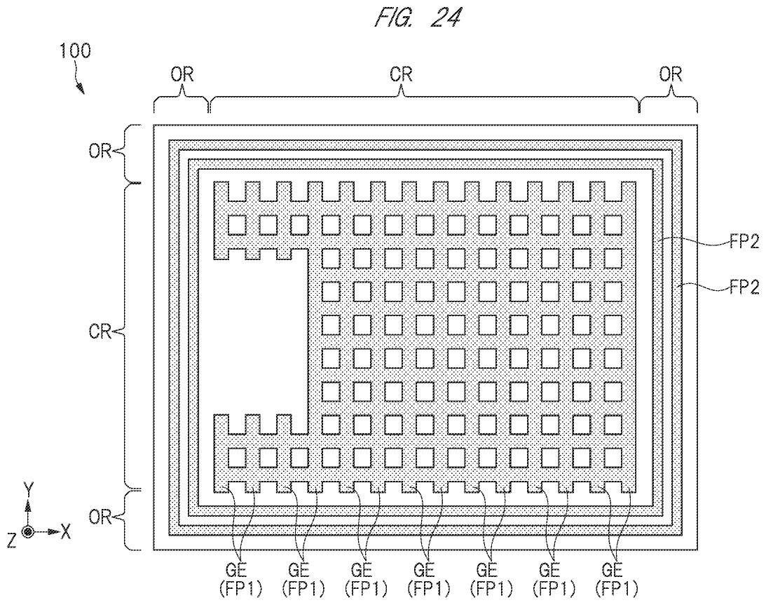

The first modification of the second embodiment will be described below with reference to FIG. 23.

In the second embodiment, the projecting portion 20 has a shape that gradually narrows. In the first modification, as shown in FIG. 23, not only the projecting portion 20 but also an end portion 30 of the trench TR1 has the shape that gradually narrows. Namely, the width of each end portion 30 of the plurality of trenches TR1 in the X direction gradually narrows as it extends toward the trench TR2. Also, the plurality of projecting portions 20 and the respective end portions 30 of the plurality of trenches TR1 are alternately arranged next to each other.

Processing the end portions 30 into such a shape makes it easier to bring the trench TR2 closer to the trench TR1 than in the second embodiment. Therefore, the withstand voltage in the outer peripheral region OR of the semiconductor device 100 can be further improved.

### Second Modification

The second modification of the first embodiment will be described below with reference to FIG. 24.

In the first embodiment, the plurality of trenches TR1 extends in the Y direction and is formed in stripes. In the second modification, the plurality of trenches TR1 has portions extending in the X direction, and the plurality of trenches TR1 is connected to each other to form a mesh pattern. Also in the second modification, the withstand voltage in the outer peripheral region OR of the semiconductor device 100 can be improved.

Note that the plurality of mesh-like trenches TR1 disclosed in the second modification can be applied also to the second embodiment or the first modification.

In the foregoing, the present invention has been specifically described based on the embodiments, but it goes without saying that the present invention is not limited to the embodiments described above and can be modified in various ways within the range not departing from the gist thereof.

What is claimed is:

1. A semiconductor device having a cell region in which a plurality of MOSFETs is formed and an outer peripheral region surrounding the cell region in plan view, the semiconductor device comprising:
a semiconductor substrate having a drift region, a conductivity type of the drift region being a first conductivity type;
a body region formed in the drift region of each of the cell region and the outer peripheral region, a conductivity type of the body region being a second conductivity type opposite the first conductivity type;
a source region formed in the body region of the cell region, a conductivity type of the source region being the first conductivity type;
a plurality of first trenches formed in the drift region of the cell region such that a bottom portion of each of the plurality of first trenches reaches a position deeper than the body region;
a second trench formed in the drift region of the outer peripheral region such that a bottom portion of the second trench reaches a position deeper than the body region;
a plurality of gate electrodes formed in the plurality of first trenches, respectively, via a gate insulating film; and
a second electrode formed in the second trench via a second insulating film,
wherein each of the plurality of first trenches extends in a first direction in plan view,
wherein the second trench extends at least in a second direction crossing the first direction in plan view,
wherein, in the drift region of the outer peripheral region, a column region is formed in a portion sandwiched, in the first direction, by a portion, which is located between two of the plurality of first trenches arranged next to each other, and the second trench, a conductivity type of the column region being the second conductivity type, and
wherein the column region is formed so as to reach a position deeper than the body region.

2. The semiconductor device according to claim 1,
wherein the column region is formed at a position spaced apart from the second trench in the first direction.

3. The semiconductor device according to claim 1, further comprising:
an interlayer insulating film formed on the semiconductor substrate so as to cover the plurality of gate electrodes and the second electrode; and
a gate wiring and a source wiring formed on the interlayer insulating film,
wherein the plurality of gate electrodes is electrically connected to the gate wiring, and
wherein the column region, the body region, the source region, and the second electrode are electrically connected to the source wiring.

4. The semiconductor device according to claim 3,
wherein a plurality of first electrodes is formed in the plurality of first trenches and below the gate insulating film and the plurality of gate electrodes via a first insulating film, respectively, and
wherein the plurality of first electrodes is electrically connected to the source wiring.

5. The semiconductor device according to claim 1,
wherein an impurity concentration of the column region is equal to or higher than that of the body region.

6. The semiconductor device according to claim 1,
wherein the second trench extends also in the first direction, and
wherein the column region is formed also in the drift region of the outer peripheral region located in a portion sandwiched in the first direction by a portion, which is between the first trench of the plurality of first trenches closest to the second trench extending in the first direction and the second trench extending in the first direction, and the second trench extending in the second direction.

7. A semiconductor device having a cell region in which a plurality of MOSFETs is formed and an outer peripheral region surrounding the cell region in plan view, the semiconductor device comprising:
a semiconductor substrate having a drift region, a conductivity type of the drift region being a first conductivity type;
a body region formed in the drift region of each of the cell region and the outer peripheral region, a conductivity type of the body region being a second conductivity type opposite the first conductivity type;
a source region formed in the body region the cell region, a conductivity type of the source region being the first conductivity type;
a plurality of first trenches formed in the drift region of the cell region such that a bottom portion of each of the plurality of first trenches reaches a position deeper than the body region;
a second trench formed in the drift region of the outer peripheral region such that a bottom portion of the second trench reaches a position deeper than the body region;
a plurality of gate electrodes formed in the plurality of first trenches, respectively, via a gate insulating film; and
a second electrode formed in the second trench via a second insulating film,
wherein each of the plurality of first trenches extends in a first direction in plan view,
wherein the second trench extends at least in a second direction crossing the first direction in plan view, and
wherein the second trench has a plurality of projecting portions, each of the plurality of projecting portions protruding in the first direction and protruding toward a portion located between the plurality of first trenches arranged next to each other.

8. The semiconductor device according to claim 7,
wherein a width of each of the plurality of projecting portions in the second direction gradually narrows as it extends toward the portion between each of the plurality of first trenches.

9. The semiconductor device according to claim 8,
wherein a width of an end portion of each of the plurality of first trenches in the second direction gradually narrows as it extends toward the second trench.

10. The semiconductor device according to claim 7, further comprising:
an interlayer insulating film formed on the semiconductor substrate so as to cover the plurality of gate electrodes and the second electrode; and
a gate wiring and a source wiring formed on the interlayer insulating film,
wherein the plurality of gate electrodes is electrically connected to the gate wiring, and
wherein the body region, the source region, and the second electrode are electrical connected to the source wiring.

11. The semiconductor device according to claim 10,
wherein a plurality of first electrodes is formed in the plurality of first trenches and below the gate insulating film and the plurality of gate electrodes via a first insulating film, respectively, and
wherein the plurality of first electrodes is electrically connected to the source wiring.

12. The semiconductor device according to claim 7,
wherein the second trench extends also in the first direction,
wherein, in plan view, the second trench has:
a first portion extending in the first direction; and
a second portion extending in the second direction, and
wherein one of the plurality of projecting portions is protruded in the first direction and is protruded toward a portion located between the first trench of the plurality of first trenches, which is closest to the second portion of the second trench, and the second portion of the second trench.
